(19) United States
(12) Patent Application Publication
(10) Pub. No.: US 2008/0223567 A1
(43) Pub. Date: Sep. 18, 2008

(54) Heat Dissipating Device

(76) Inventor: Robert Liang, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 11/685,747

(22) Filed: Mar. 13, 2007

(51) Int. Cl. H05K 7/20

(52) U.S. Cl. 165/185; 361/704; 257/719

(57) ABSTRACT

A heat dissipating device includes a heat sink having a base with an upper surface and a lower surface, and a plurality of heat dissipating elements disposed on the upper surface of the base; a clip having a frame matching with a contour of the base, wherein the frame has a positioning portion for preventing the base from displacement, at least a first fastener defined at an inner rim of the frame, and at least two second fasteners respectively defined at an outer rim of the frame, each of which has a through hole, such that the heat sink is able to be fixed by engaging the positioning portion with base and fastening the first fastener to the heat dissipating elements.

### BACKGROUND OF THE INVENTION

1. Field of the Invention

The present invention relates to a heat dissipating device, particularly to a heat dissipating device with a detachable clip, wherein a heat sink can be integrally molded, so as to simplify the manufacturing process and save the manufacturing time. Furthermore, with the separation of the clip and the heat sink, the heat sink can be mounted on different types of motherboards by means of the clips with difference sizes, and thereby the cost can be remarkably saved.

2. The Prior Arts

Referring to FIG. 1, a conventional heat sink 1 includes a base, a plurality of heat fins 2 formed on an upper surface of a base, and a plurality of fixing portions 3 formed on a side of the base by second working. Each of the fixing portions 3 has a through hole 4. The heat sink 1 is fixed on a circuit board 7 by inserting a fixing pin 5 through the through hole 4 of the fixing portions 3 and into a fixing hole 6 on the circuit board 7, such that a lower surface of the base can be closely attached to a chip 8 of the circuit board 7. Because the position of the fixing holes 6 formed on each circuit board 7 are different according to the different specification of the chip 8, the heat sink 1 with an integrally formed fixing portion 3 is hard to use. Due to the reason, the heat sinks 1 with different sizes are required, which increases the cost for storage and the difficulty on management.

### SUMMARY OF THE INVENTION

The present invention provides a heat dissipating device with a detachable clip. In the present invention, the heat sink can be integrally molded, so as to simplify the manufacturing process and save the manufacturing time. Furthermore, with the separation of the clip and the heat sink, the heat sink can be mounted on different types of motherboards by means of clips having difference sizes, and thereby cost can be remarkably saved.

To achieve the above-mentioned objectives, a heat dissipating device in accordance with present invention comprises a heat sink having a base with an upper surface and a lower surface, and a plurality of heat dissipating elements disposed on the upper surface of the base; a clip having a frame matching with a contour of the base, wherein the frame has a positioning portion for preventing the base for displacement, at least a first fastener defined at an inner rim of the frame, and at least two second fasteners respectively defined at an outer rim of the frame, each of which has a through hole, such that the heat sink can be fixed by engaging the positioning portion with base and fastening the first fastener to the heat dissipating elements.

### BRIEF DESCRIPTION OF THE DRAWINGS

The present invention will be apparent to those skilled in the art by reading the following detailed description of preferred embodiments thereof, with reference to the attached drawings, in which:

FIG. 1 is an exploded perspective view showing a conventional heat sink assembly.

FIG. 2 is an exploded perspective view showing a heat dissipating device in accordance with a first embodiment of the present invention.

FIG. 3A is a schematic view showing a first operating state of a heat dissipating device in accordance with the first embodiment of the present invention.

FIG. 3B is a schematic view showing a second operating state of a heat dissipating device in accordance with the first embodiment of the present invention.

FIG. 4 is an exploded perspective view showing a heat dissipating device in accordance with a second embodiment of the present invention.

FIG. 5A is a schematic view showing a first operating state of a heat dissipating device in accordance with the second embodiment of the present invention.

FIG. 5B is a schematic view showing a second operating state of a heat dissipating device in accordance with the second embodiment of the present invention.

FIG. 6 is an exploded perspective view showing a heat dissipating device in accordance with a third embodiment of the present invention.

FIG. 7A is a schematic view showing a first operating state of a heat dissipating device in accordance with the third embodiment of the present invention.

FIG. 7B is a schematic view showing a second operating state of a heat dissipating device in accordance with the third embodiment of the present invention.

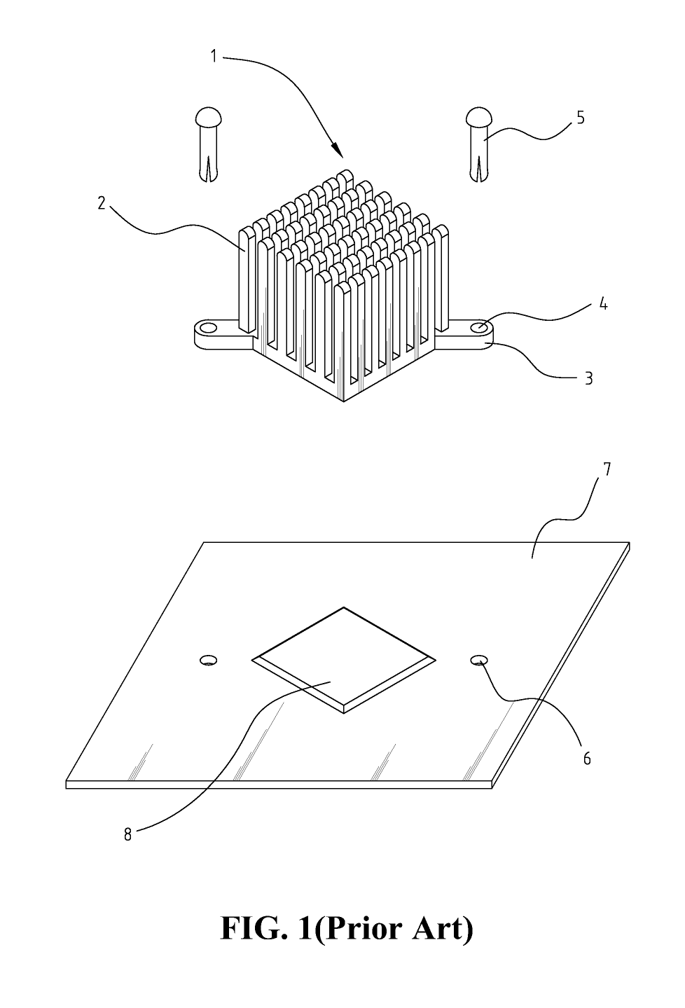

### DETAILED DESCRIPTION OF THE PREFERRED EMBODIMENT

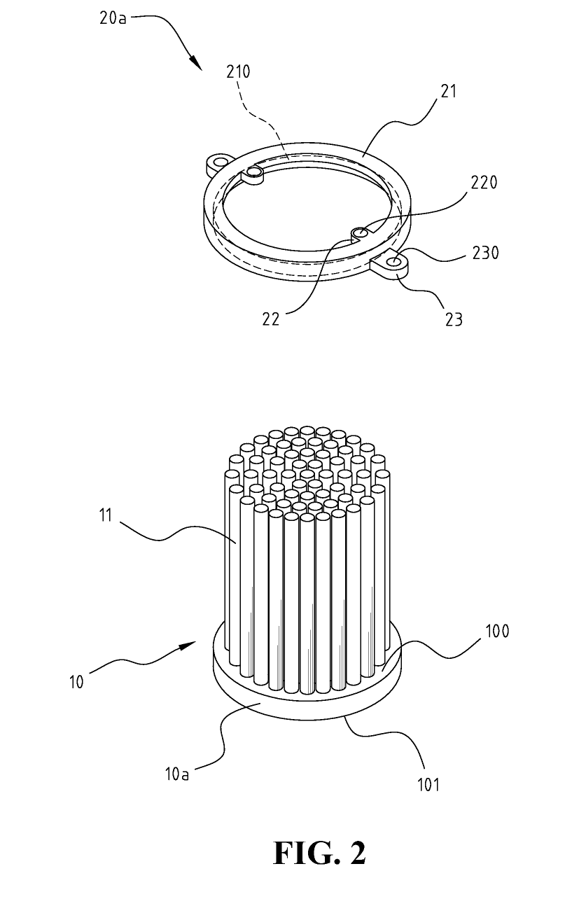

Referring to FIG. 2, a heat dissipating device in accordance with a first embodiment of the present invention comprises a heat sink 10 and a clip 20a. The heat sink 10 includes a circular base 10a with an upper surface 100 and a lower surface 101, and a plurality of heat dissipating elements 11 disposed on the upper surface 100 of the circular base 10a. The clip 20a includes an annular frame 21 matching with a contour of the circular base 10a. The annular frame 21 has a slot 210 (positioning portion), two first fasteners 22 respectively formed at an inner rim of the fame 21, and two second fasteners 23 respectively formed at an outer rim of the frame 21. Each of the first fasteners 22 has a first through hole 220, and each of the second fasteners 23 has a second through hole 230. After the first through hole 220 of the first fastener 22 sleeved on one of the heat dissipating elements 11, the clip 20a can be connected on the upper surface 100 of the circular base 10a by engaging the slot 210 of the annular frame 21 with circular base 10a.

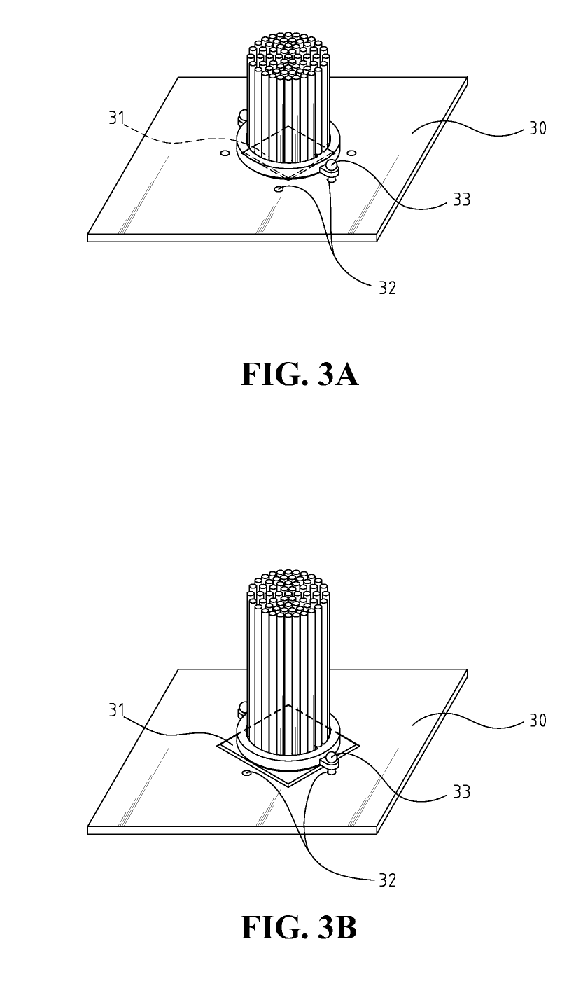

As shown in the FIGS. 3A and 3B, when the clip 20a is sleeved on the circular base 10a of the heat sink 10, the heat sink 10 can be fixed on a circuit board 30 by inserting a fixing pin 33 through the second through hole 230 of the second fastener 23 and into a fixing hole 32 of the circuit board 30, such that the lower surface 101 of the circular base 10a is closely attached with a chip 31 on the circuit board 30 for dissipating heat from the chip 31. Referring to FIG. 3A, when an area of the chip 31 is smaller than an area of the circular base 10a, the heat dissipating elements 11 of the heat sink 10 has a shorter length. Referring to FIG. 3B, when the area of the chip 31 is greater than the area of the circular base 10a, the heat dissipating elements 11 of the heat sink 10 has a longer length.

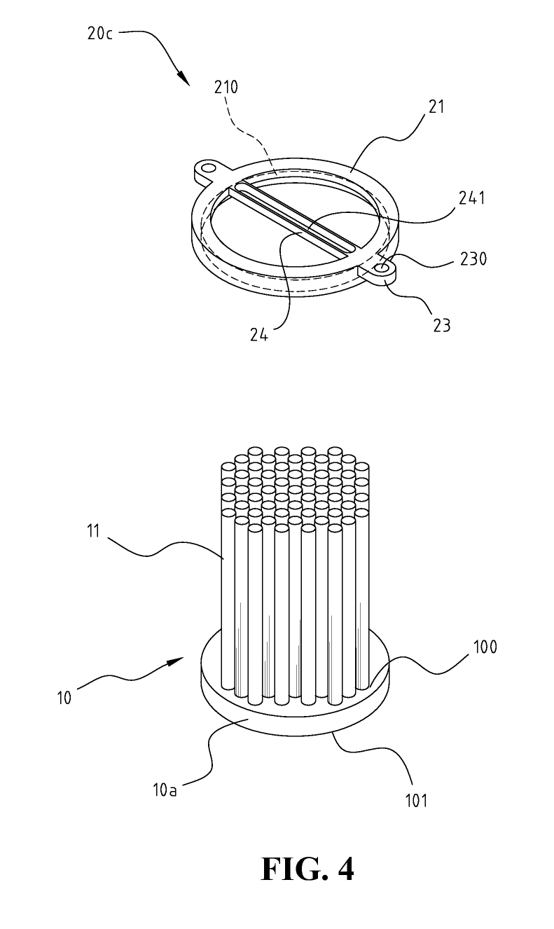

Referring to FIG. 4, a heat dissipating device in accordance with a second embodiment of the present invention comprises a heat sink 10 and a clip 20a. The heat sink 10 includes a circular base 10a with an upper surface 100 and a lower surface 101, and a plurality of heat dissipating elements 11 disposed on the upper surface 100 of the circular base 10a. The clip 20a has an annular frame 21 matching with a contour of the circular base 10a. The annular frame 21 has a slot 210 (positioning portion), two parallel rods 24 extended from an inner rim of the fame 21, and two second fasteners 23 respectively formed at an outer rim of the frame 21. The two parallel rods 24 have an interspace 241 formed therebetween for passing a row of the heat dissipating elements 11. Each of the second fasteners 23 has a second through hole 230. After the interspace 241 between the parallel rods 24 sleeved on a row of heat dissipating elements 11, the clip 20a can be connected on the upper surface 100 of the circular base 10a by engaging the slot 210 of the annular frame 21 with the circular base 10a.

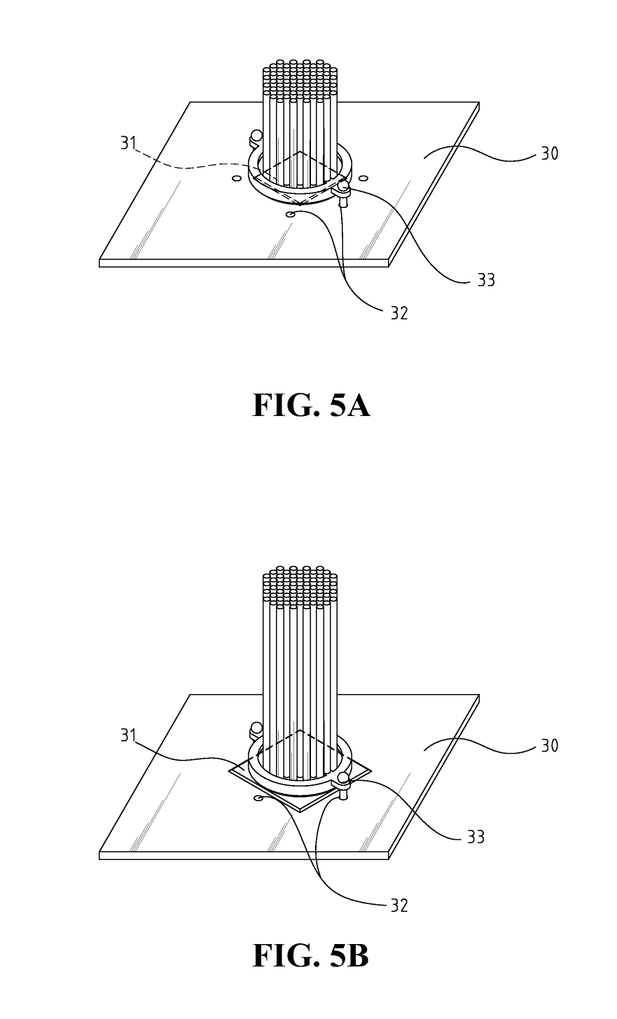

As shown in the FIGS. 5A and 5B, when the clip 20a is sleeved on the circular base 10a of the heat sink 10, and the heat sink 10 can be fixed on a circuit board 30 by inserting a fixing pin 33 through the second through hole 230 of the second fastener 23 and into a fixing hole 32 of the circuit board 30, such that the lower surface 101 of the circular base 10a is closely attached with a chip 31 on the circuit board 30 for dissipating heat from the chip 31. Referring to FIG. 5A, when an area of the chip 31 is smaller than an area of the circular base 10a, the heat dissipating elements 11 of the heat sink 10 has a shorter length. Referring to FIG. 5B, when the area of the chip 31 is greater than the area of the circular base 10a, the heat dissipating elements 11 of the heat sink 10 has a longer length.

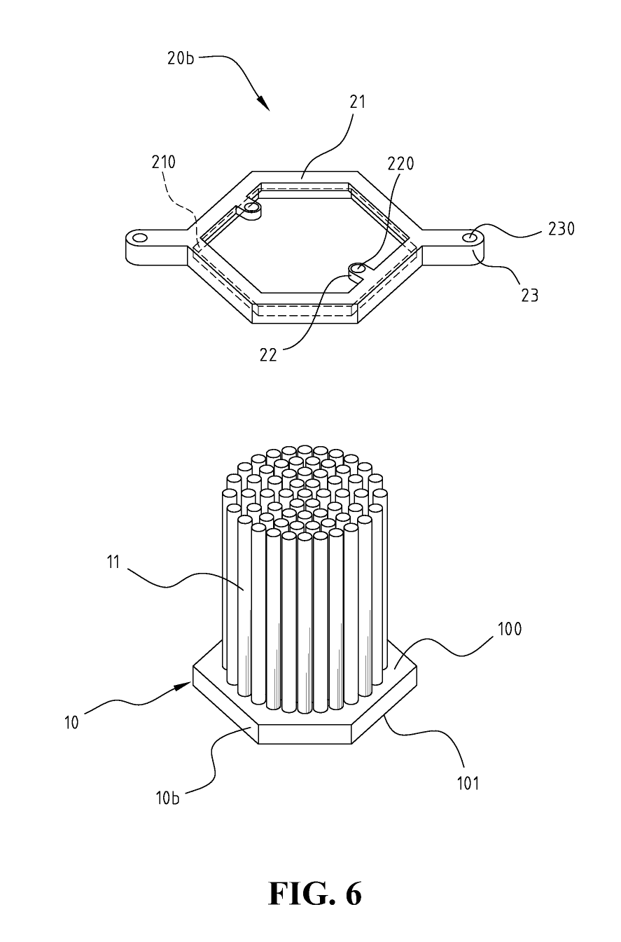

Referring to FIG. 6, a heat dissipating device in accordance with a third embodiment of the present invention comprises a heat sink 10 and a clip 20b. The heat sink 10 has a hexagonal base 10b with an upper surface 100 and a lower surface 101, and a plurality of heat dissipating elements 11 disposed on the upper surface 100 of the hexagonal base 10b. The clip 20b has a hexagonal frame 21 matching with a contour of the hexagonal base 10b. The hexagonal frame 21 has a slot 210 (positioning portion), two first fasteners 22 respectively formed at an inner rim of the clip fame 21, and two second fasteners 23 respectively formed at an outer rim of the frame 21. Each of the first fasteners 22 has a first through hole 220, and each of the second fasteners 23 has a second through hole 230. After the first through hole 220 of the first fastener 22 sleeved on one of the heat dissipating elements 11, the annular clip 20b can be connected on the upper surface 100 of the hexagonal base 10b by engaging the slot 210 of the hexagonal frame 21 with hexagonal base 10b.

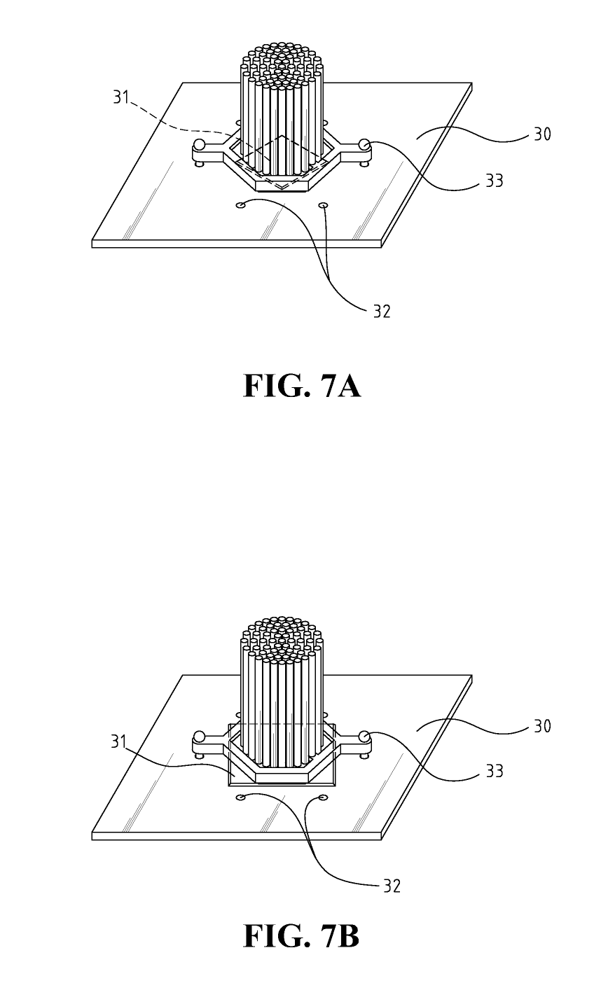

As shown in the FIGS. 7A and 7B, when the hexagonal clip 20b is sleeved on the hexagonal base 10b of the heat sink 10, the heat sink 10 can be fixed on a circuit board 30 by inserting a fixing pin 33 through the second through hole 230 of the second fastener 23 and into a fixing hole 32 of the circuit board 30, such that the lower surface 101 of the hexagonal base 10b is closely attached with a chip 31 on the circuit board 30 for dissipating heat from the chip 31. Referring to FIG. 7A, when an area of the chip 31 is smaller than an area of the hexagonal base 10b, the heat dissipating elements 11 of the heat sink 10 has a shorter length. Referring to FIG. 7B, when the area of the chip 31 is greater than the area of the hexagonal base 10b, the heat dissipating elements 11 of the heat sink 10 has a longer length.

The abovementioned heat sink can be integrally molded, so as to save manufacturing time and simplify the manufacturing process. Furthermore, with separation of the clip and the heat sink, the heat sink can be mounted on different types of motherboards by means of clips with various sizes, such that the cost can be remarkably saved. Moreover, the length of the heat dissipating elements of the heat sink can be adjusted properly to manufacture according to the demands

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heat dissipating device, comprising:
a heat sink having a base with an upper surface and a lower surface, and a plurality of heat dissipating elements disposed on the upper surface of the base;
a clip having a frame matching with a contour of the base, wherein the frame includes a positioning portion for preventing the base from displacement.

2. The heat dissipating device as claimed in claim 1, wherein the clip comprises at least a first fastener formed at an inner rim of the frame, and at least two second fasteners respectively formed at an outer rim of the frame, each of which has a through hole, such that the heat sink is able to be fixed by engaging the positioning portion with the base and fastening the first fastener to the heat dissipating elements.

3. The heat dissipating device as claimed in claim 1, wherein the base is a polygonal shape, and the frame is a polygonal shape matching with the base.

4. The heat dissipating device as claimed in claim 1, wherein the base is a circular shape, and the frame is an annular shape matching with the base.

5. The heat dissipating device as claimed in claim 2, wherein the first fasteners are two parallel rods extended from the inner rim of the frame.
